(19) United States
(12) Patent Application Publication
(10) Pub. No.: US 2026/0163572 A1
(43) Pub. Date: Jun. 11, 2026

(54) ISOLATOR SIGNAL DETECTION

(71) Applicant: Texas Instruments Incorporated, Dallas, TX (US)

(72) Inventors: Sooping SAW, McKinney, TX (US); Adam KINSEL, Dallas, TX (US); Masahiro YOSHIOKA, Plano, TX (US)

(73) Assignee: Texas Instruments Incorporated, Dallas, TX (US)

(21) Appl. No.: 19/192,256

(22) Filed: Apr. 28, 2025

Related U.S. Application Data
(60) Provisional application No. 63/730,638, filed on Dec. 11, 2024.

(51) Int. Cl. H03K 17/689

(52) U.S. Cl. CPC H03K 17/689; H03K 2217/0063

(57) ABSTRACT

A circuit includes a capacitive isolator, a rectifier circuit, first and second receivers, and a switch. The capacitive isolator has first and second inputs, and first and second outputs. The rectifier circuit has first and second terminals respectively coupled to the first and second outputs of the capacitive isolator, a third terminal, and a fourth terminal. The first receiver has a first input coupled to the first output of the capacitive isolator, a second input coupled to second output of the capacitive isolator, and an output. The second receiver has a first input coupled to the third terminal of the rectifier circuit, a second input coupled to the fourth terminal of the rectifier circuit, an enable input coupled to the output of the first receiver, and an output. The switch has a control input coupled to the output of the second receiver.

### CROSS-REFERENCE TO RELATED APPLICATIONS

This application claims priority to U.S. Provisional Application No. 63/730,638, filed Dec. 11, 2024, entitled “Dynamic Active Signal Detection During GNT (Ground Noise Transient) for Isolation Switch,” which is hereby incorporated by reference in its entirety.

### BACKGROUND

Isolation is useful in electrical circuits to prevent the flow of direct currents and undesirable alternating currents between two parts of a system. While preventing flow of undesirable currents between parts of a system, isolation may allow signal transfer between the isolated parts of the system. Isolation may be provided by integrated circuits referred to as isolators. Electronic systems may include isolators for safety reasons and/or to protect electronic components of the systems. For example, where two systems need to communicate, but the systems have grounds that may be at different potentials, communication may be through an isolator that is tied to the grounds of both systems, but which limits current flow between the grounds. Various types of isolators may include optical coupling, capacitive coupling, inductive coupling, or other types of coupling to isolate systems while allowing communication between the systems.

### SUMMARY

In one example, an apparatus includes a rectifier circuit, first and second capacitors, a driver circuit, first and second receivers, and a switch. The rectifier circuit has a first terminal, a second terminal, a third terminal, and a fourth terminal. The first capacitor has a first terminal coupled to the first terminal of the rectifier circuit, and a second terminal. The second capacitor has a first terminal coupled to the second terminal of the rectifier circuit, and a second terminal. The driver circuit has a first output coupled to the first terminal of the first capacitor, and a second output coupled to the second terminal of the second capacitor. The first receiver has a first input coupled to the first terminal of the rectifier circuit, a second input coupled to the second terminal of the rectifier circuit, and an output. The second receiver has a first input coupled to the third terminal of the rectifier circuit, a second input coupled to the second terminal of the rectifier circuit, an enable input coupled to the output of the first receiver, and an output. The switch has a control input coupled to the output of the second receiver.

In another example, a circuit includes a capacitive isolator, a rectifier circuit, first and second receivers, and a switch. The capacitive isolator has a first input, a second input, a first output, and a second output. The rectifier circuit has a first terminal coupled to the first output of the capacitive isolator, and a second terminal coupled to the second output of the capacitive isolator, a third terminal, and a fourth terminal. The first receiver has a first input coupled to the first output of the capacitive isolator, a second input coupled to second output of the capacitive isolator, and an output. The second receiver has a first input coupled to the third terminal of the rectifier circuit, a second input coupled to the fourth terminal of the rectifier circuit, an enable input coupled to the output of the first receiver, and an output. The switch has a control input coupled to the output of the second receiver.

In a further example, a switch circuit includes a pass transistor, a transistor driver, a rectifier circuit, first and second receivers, a capacitive isolator, and a differential driver. The pass transistor has a first terminal coupled to an input terminal, a second terminal coupled to an output terminal, and a control terminal. The transistor driver has an input, an output coupled to the control terminal of the pass transistor, and an input. The rectifier circuit has a first terminal, a second terminal, a third terminal, and a fourth terminal. The first receiver has a first terminal coupled to the first terminal of the rectifier circuit, a second terminal coupled to the second terminal of the rectifier circuit, and an output coupled to the input of the transistor driver. The second receiver has a first terminal coupled to the third terminal of the rectifier circuit, a second terminal coupled to the fourth terminal of the rectifier circuit, and an output coupled to the input of the transistor driver. The capacitive isolator has a first input, a second input, a first output coupled to the first terminal of the rectifier circuit, and a second output coupled to the second terminal of the rectifier circuit. The differential driver has a first output coupled to the first input of the capacitive isolator, and a second output coupled to the second input of the capacitive isolator.

### BRIEF DESCRIPTION OF THE DRAWINGS

FIG. 1 is a block diagram of an example circuit that includes a capacitive isolator and receiver circuitry that provides ground noise immunity and reduced power consumption.

FIG. 2 is a schematic diagram of the circuit of FIG. 1 showing example internal circuitry.

FIG. 3 is a schematic diagram of an example isolated high-side switch circuit using the circuitry of FIG. 2.

FIG. 4 is a schematic diagram of an example automotive insulation measurement circuit that includes the isolated high-side switch circuit of FIG. 2 or FIG. 3.

### DETAILED DESCRIPTION

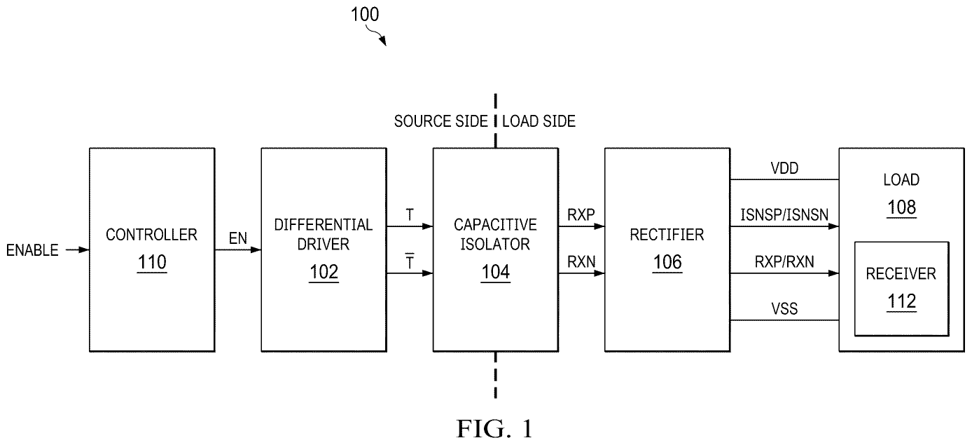

FIG. 1 is a block diagram of an example circuit 100 that includes a capacitive isolator and receiver circuitry that provide ground noise immunity and reduced power consumption. The circuit 100 includes a differential driver 102, a capacitive isolator 104, a rectifier 106, a load circuit 108, and a controller 110. The capacitive isolator 104 capacitively isolates the circuitry on the load side of the capacitive isolator 104 from circuitry on the source side of the capacitive isolator 104. For example, the ground voltage used on the load side of the capacitive isolator 104 may be significantly different from the ground voltage used on the source side of the capacitive isolator 104.

In examples of the circuit 100, the controller 110 has an input at which a control signal (ENABLE) may be received, and an output, at which a control signal (EN) may be provided. EN may be a square wave signal, a triangle wave signal, etc. having a frequency selected to facilitate propagation through the capacitive isolator 104. The controller 110 may generate EN (e.g., provide an oscillating signal) at the output of the controller 110 responsive to ENABLE having a first logic state (e.g., a logic high state). The controller 110 may not generate EN (e.g., provide a non-oscillating signal) at the output of the controller 110 responsive to ENABLE having a second logic state (e.g., a logic low state).

The differential driver 102 has an input coupled to the output of the controller 110 for receipt of EN. The differential driver generates differential signals T and T̅ based on EN. T and T̅ may be a differential version of EN. The differential driver 102 has first and second outputs at which the differential driver 102 provides T and T̅.

The capacitive isolator 104 has a first input coupled to the first output of the differential driver 102 for receipt of T. The capacitive isolator 104 has a second input coupled to the second output of the differential driver 102 for receipt of T̅. The capacitive isolator 104 includes capacitors that pass T and T̅, and block DC. The capacitive isolator 104 has a first output and a second output at which signals passed by the capacitors of the capacitive isolator 104 are provided. The differential signals provided at the outputs of the capacitive isolator 104 are labeled RXP and RXN.

The rectifier 106 receives and rectifies RXP and RXN, and provides VDD and VSS to power the load circuit 108. The rectifier 106 has a first terminal coupled to the first output of the capacitive isolator 104 for receipt of RXP. The rectifier 106 has a second terminal coupled to the second output of the capacitive isolator 104 for receipt of RXN. The rectifier 106 has a third terminal at which VDD is provided, and a fourth terminal at which VSS is provided. The rectifier 106 also senses current flow in rectifiers of the rectifier 106, and provides current sense signals (ISNSP and ISNSN) for use by the load circuit 108 that are based on the current flow in rectifiers of the rectifier 106. The rectifier 106 has fifth and sixth terminals at which ISNSP and ISNSN are provided.

The load circuit 108 may be any circuit that can be powered by VDD and VSS provided by the rectifier 106. The load circuit 108 includes receiver circuit 112 that receives RXP and RXN, and ISNSP and ISNSN. The receiver circuit 112 uses RXP, RXN, ISNSP and ISNSN to determine whether differential signals are being transmitted through the capacitive isolator 104. If a differential signal is detected (e.g., a differential signal is being transmitted through the capacitive isolator 104), then the load circuit 108 may perform a selected function (e.g., close a switch). If a differential signal is not detected, then the load circuit 108 may not perform the selected function (e.g., open the switch). The receiver circuit 112 is powered by VDD and VSS provided by the rectifier 106.

The receiver circuit 112 has a first terminal (an input voltage terminal) coupled to the rectifier 106 for reception of VDD, and a second terminal (a reference terminal) coupled to the rectifier 106 for reception of VSS. The receiver circuit 112 has a first input coupled to the first terminal of the rectifier 106 for receipt of RXP, and a second input coupled to the second terminal of the rectifier 106 for receipt of RXN. The receiver circuit 112 has a third input coupled to the fifth terminal of the rectifier 106 for receipt of ISNSP, and a fourth input coupled to the sixth terminal of the rectifier 106 for receipt of ISNSN.

The signals RXP and RXN provided by the capacitive isolator 104 are relatively weak (e.g., 10-20 microamperes of current) and are therefore susceptible to corruption by ground noise transients that propagate through parasitic capacitance from VSS. Ground noise transients may drive RXP and RXN to VDD or VSS, causing RXP and RXN to become non-differential. If the differential signal is not detected using RXP and RXN, then the receiver circuit 112 can detect the differential signal using ISNSP and ISNSN, which are not corrupted by the ground noise transients. Using ISNSP and ISNSN to detect differential signals may consume substantially more power than using RXP and RXN to detect differential signals. To reduce power consumption, the receiver circuit 112 enables (e.g., powers) circuitry that uses ISNSP and ISNSN to detect differential signals responsive to detection of no differential signal using RXP and RXN. Reduction of power consumption of the receiver circuit allows the current provided by the capacitive isolator 104 to be reduced by reducing the size of the capacitors of the capacitive isolator 104. Reducing the size of the capacitors of the capacitive isolator 104 allows the circuit area of an integrated circuit including the circuit 100 to be reduced.

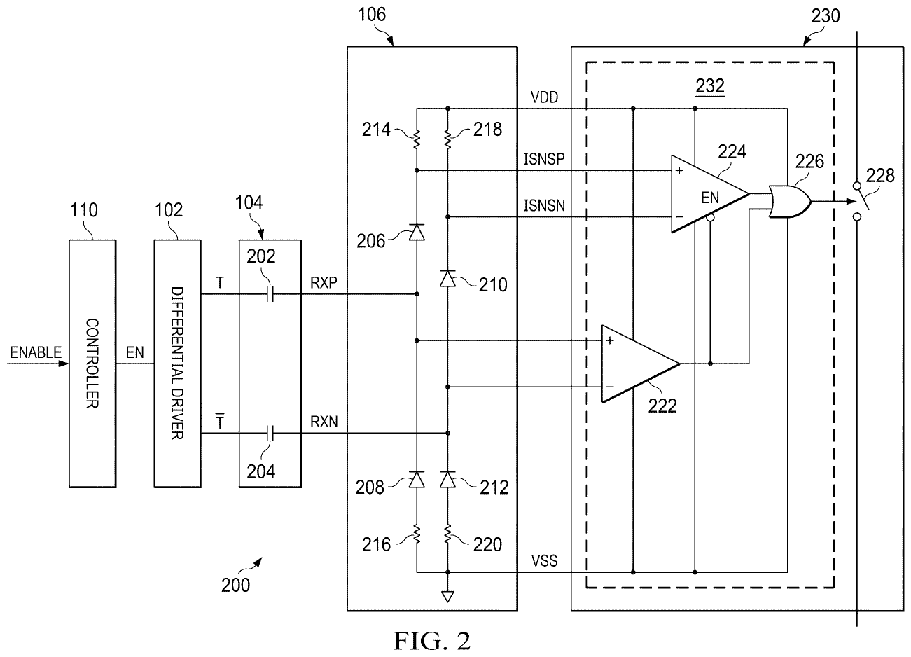

FIG. 2 is a schematic diagram of a circuit 200 showing example internal circuitry of various blocks. The circuit 200 is an example of the circuit 100. The circuit 200 includes a load circuit 230. The load circuit 230 is an example of the load circuit 108. In the circuit 200, the capacitive isolator 104 includes capacitors 202 and 204. The capacitor 202 has a first terminal coupled to the first output of the differential driver 102. The capacitor 202 has a second terminal coupled to the first terminal of the rectifier 106. The capacitor 204 has a first terminal coupled to the second output of the differential driver 102. The capacitor 204 has a second terminal coupled to the second terminal of the rectifier 106.

In the example of the circuit 200 shown in FIG. 2, the rectifier 106 includes a full wave rectifier circuit. The rectifier 106 includes diodes 206, 208, 210, and 212, and resistors 214, 216, 218, and 220. The diode 206 has a cathode terminal coupled to the receiver circuit 232. ISNSP is provided at the cathode of the diode 206. The diode 206 has an anode terminal coupled to the second terminal of the capacitor 202. The diode 208 has a cathode terminal coupled to the anode terminal of the diode 206. The diode 208 has an anode terminal coupled to the reference terminal via the resistor 216. The diode 210 has a cathode terminal coupled to the receiver circuit 232. ISNSN is provided at the cathode of the diode 210. The diode 210 has an anode terminal coupled to the second terminal of the capacitor 204. The diode 212 has a cathode terminal coupled to the anode terminal of the diode 210. The diode 212 has an anode terminal coupled to the reference terminal via the resistor 220.

The resistor 216 has a first terminal coupled to the anode of the diode 208, and a second terminal coupled to the reference terminal. The resistor 220 has a first terminal coupled to the anode of the diode 212, and a second terminal coupled to the second terminal of the 216. The resistor 214 has a first terminal coupled to the cathode of the diode 206, and a second terminal coupled to the input voltage terminal of the load circuit 230. The resistor 218 has a first terminal coupled to the cathode of the diode 210, and a second terminal coupled to the input voltage terminal of the load circuit 230. Current flow through the resistor 214 produces ISNP, and current flow through the resistor 218 produces ISNSN.

The load circuit 230 includes a receiver circuit 232 and a switch 228. The receiver circuit 232 is an example of the receiver circuit 112. The switch 228 has a first terminal coupled to a first external terminal of the circuit 200, and a second terminal coupled to a second external terminal of the circuit 200. The switch 228 has a control input coupled to an output of the receiver circuit 232. The switch 228 is opened or closed responsive to a control signal provided at the output of the receiver circuit 232. In some examples of the load circuit 230, the switch 228 may be replaced by different circuitry controlled by the control signal provided at the output of the receiver circuit 232.

The receiver circuit 232 includes a receiver 222, a receiver 224, and a logic gate 226. The receiver 222, the receiver 224, and the logic gate 226 are powered by VDD and VSS received from the rectifier 106. The receiver 222 has an input voltage terminal coupled to the second terminal of the resistor 218 for receipt of VDD, and a reference terminal coupled to the second terminal of the resistor 220 for receipt of VSS. The receiver 224 has an input voltage terminal coupled to the second terminal of the resistor 218 for receipt of VDD, and a reference terminal coupled to the second terminal of the resistor 220 for receipt of VSS. The logic gate 226 has an input voltage terminal coupled to the second terminal of the resistor 218 for receipt of VDD, and a reference terminal coupled to the second terminal of the resistor 220 for receipt of VSS.

The receiver 222 detects differential signals using RXP and RXN to detect differential voltage. The receiver 222 has a first input (e.g., a non-inverting input) coupled to the second terminal of the capacitor 202, and a second input (e.g., an inverting input) coupled to the second terminal of the capacitor 204. The receiver 222 has an output at which a detection signal is provided. The detection signal provided at the output of the receiver 222 indicates whether RXP and RXN are differential.

The receiver 224 detects differential signal using ISNSP and ISNSN to detect differential current. The receiver 224 has a first input (e.g., a non-inverting input) coupled to the cathode of the diode 206, and a second input (e.g., an inverting input) coupled to the cathode of the diode 210. The receiver 222 has an output at which a detection signal is provided. The detection signal provided at the output of the receiver 224 indicates whether ISNSP and ISNSN are differential. The receiver 224 has an enable input coupled to the output of the receiver 222. If the detection signal provided at the output of the receiver 222 indicates that no differential signal is detected using RXP and RXP, then the receiver 224 is enabled (e.g., powered) to determine whether a differential signal is detected using ISNSP and ISNSN. If the detection signal provided at the output of the receiver 222, indicates that differential signal is detected using RXP and RXP, then the receiver 224 is disabled (e.g., not powered).

The logic gate 226 combines the detection signals provided by the receiver 222 and the receiver 224 to produce the control signal that is provided to the switch 228. The logic gate 226 may a logic OR gate. For example, if either of the detection signals provided the receiver 222 or the receiver 224 indicate that a differential signal is detected, then the control signal provided to the switch 228 may have a state (e.g., a logic high) that causes the switch 228 to close. If neither of the detection signals provided by the receiver 222 or the receiver 224 indicate that a differential signal is detected, then the control signal provided to the switch 228 may have a state (e.g., a logic low) that causes the switch 228 to open. The logic gate 226 has a first input coupled to the output of the receiver 222, a second input coupled to the output of the receiver 224, and an output coupled to the control input of the switch 228.

Because ISNSP and ISNSN are relatively low amplitude signals (e.g., less than 50 millivolts) the bandwidth and power consumption of the receiver 224 may be relative high. For example, if enabled the receiver 224 may consume most (e.g., 65%) of the power provided by the rectifier 106. By enabling the receiver 224 only if the receiver 222 does not detect differential signal using RXP and RXN, the receiver circuit 232 significantly reduces the power consumption of the load circuit 230. The reduced power consumption allows the size of the capacitors 202 and 204 to be reduced, which reduces the circuit area of the circuit 200.

When a common mode noise transient occurs that causes RXP and RXN to become non-differential, the power drawn from RXP and RXN by the rectifier 106 may be insufficient to power the receiver circuit 232 (with enabling of the receiver 224). In the circuit 200, the rectifier 106 rectifies the common mode noise signal, and the power harvested from the common noise signal is used to power the receiver 224 and other circuitry of the receiver circuit 232. Accordingly, the receiver 224 is powered even if no power is being drawn from RXP and RXN during a common mode noise transient.

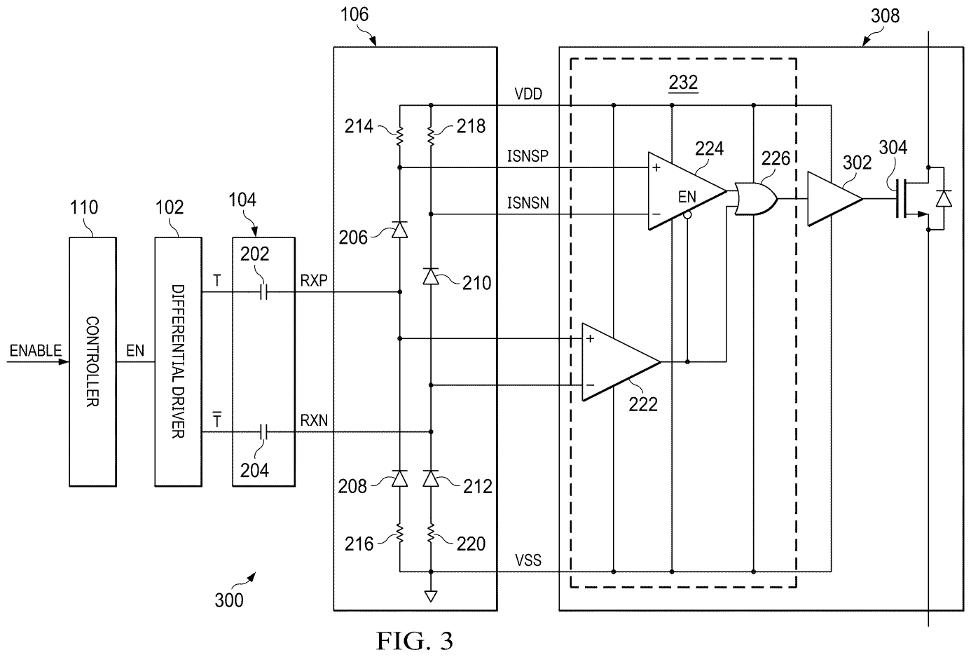

FIG. 3 is a schematic diagram of an example isolated high-side switch circuit 300. The isolated high-side switch circuit 300 is an example of the circuit 100, and includes a load circuit 308. The load circuit 308 is an example of the load circuit 230, and includes the receiver circuit 232. The load circuit 308 also includes a transistor 304 and a transistor driver 302 to implement the switch 228. The transistor 304 may be an n-channel field effect transistor (NFET) is some examples of the load circuit 308. The transistor 304 is a pass transistor that conducts current between a first external terminal of the isolated high-side switch circuit 300 and a second external terminal of the isolated high-side switch circuit 300. The transistor 304 has a first terminal (e.g., drain) coupled to a first external terminal of the isolated high-side switch circuit 300. The transistor 304 has a second terminal (e.g., source) coupled to a second external terminal of the isolated high-side switch circuit 300. The transistor 304 has a control terminal (e.g., gate) coupled to the transistor driver 302. Control signal received from the transistor driver 302 turns the transistor 304 on or off to enable or disable current flow through the transistor 304.

The transistor driver 302 is powered by VDD and VSS received from the rectifier 106. The transistor driver 302 has an input voltage terminal coupled to the third terminal of the rectifier 106 for receipt of VDD. The transistor driver 302 has a reference terminal coupled to the fourth terminal of the rectifier 106 for receipt of VSS. The transistor driver 302 has an output coupled to the control terminal of the transistor 304. The transistor driver 302 has an input coupled to the output of the logic gate 226. If the transistor driver 302 is powered (by VDD and VSS provided by the rectifier 106), the transistor driver 302 generates the control signal provided to the control terminal of the transistor 304 responsive to the control signal provided at the output of the logic gate 226. The transistor driver 302 generates the control signal provided to the transistor 304 with voltage and current suitable for turning the transistor 304 on or off.

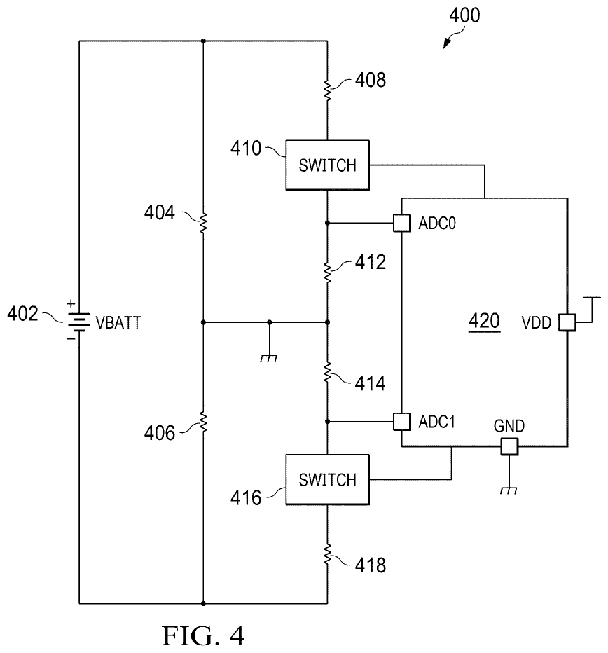

FIG. 4 is a schematic diagram of an example automotive insulation measurement circuit 400 that includes the isolated high-side switch circuit 300. The automotive insulation measurement circuit 400 includes a battery 402, resistors 404, 406, 408, 412, 414, and 418, high-side switches 410 and 416, and a controller 420. The high-side switches 410 and 416 may be examples of the isolated high-side switch circuit 300. The battery 402 may be an electric vehicle battery pack that provides a high voltage (e.g., 400-800 volts). The controller 420 may be a microcontroller or other processor.

The battery 402 has a positive terminal and a negative terminal. The resistor 404 is coupled between the positive terminal of the battery 402 and chassis ground. The resistor 404 has a first terminal coupled to the positive termina of the battery 402, and a second terminal coupled to chassis ground. The resistor 406 is coupled between the negative terminal of the battery 402 and chassis ground. The resistor 406 has a first terminal coupled to the negative terminal of the battery 402, and a second terminal coupled to chassis ground.

The resistor 408 is coupled between the positive terminal of the battery 402 and the high-side switch 410. The resistor 408 has a first terminal coupled to the positive terminal of the battery 402. A second terminal of resistor 408 is coupled to a first external terminal of the high-side switch 410. A second external terminal of the high-side switch 410 is coupled to chassis ground via the resistor 412. A first terminal of the resistor 412 is coupled to the second external terminal of the high-side switch 410, and a second terminal of the resistor 412 is coupled to chassis ground. A control input of the high-side switch 410 is coupled to the controller 420.

The resistor 418 is coupled between the negative terminal of the battery 402 and the high-side switch 416. The resistor 418 has a first terminal coupled to the negative terminal of the battery 402, and a second terminal couple to a first external terminal of the high-side switch 416. A second external terminal of the high-side switch 416 is coupled to chassis ground via the resistor 414. A first terminal of the resistor 414 is coupled to the second external terminal of the high-side switch 416, and a second terminal of the resistor 414 is coupled to chassis ground. A control input of the high-side switch 416 is coupled to the controller 420.

The controller 420 has a reference terminal coupled to chassis ground. The controller 420 has an input voltage terminal coupled to a voltage regulator (not shown) that is also referenced to chassis ground. The controller 420 has a first output coupled to the control input of the high-side switch 410, and a second output coupled to the control input of the high-side switch 416. The controller 420 makes a first measurement with the high-side switch 416 open and the high-side switch 410 closed, and makes a second measurement with the high-side switch 416 closed and the high-side switch 410 open. The controller 420 computes the resistance between the positive and negative terminals of the battery 402 and ground based on the two measurements.

FIG. 4 illustrates one example application of the circuit 200 or the isolated high-side switch circuit 300. Examples of the circuit 100 may be used to provide switching with improved ground noise transient immunity and reduced power consumption in any application that uses an isolation circuit.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

As used herein, the terms “terminal,” “node,” “interconnection,” “pin” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors is described herein, other transistors (or equivalent devices) may be used instead with little or no change to the remaining circuitry. For example, a field effect transistor (“FET”) (such as an n-channel FET (NFET) (n-type transistor) or a p-channel FET (PFET) ) (p-type transistor)), a bipolar junction transistor (BJT—e.g., NPN transistor or PNP transistor), an insulated gate bipolar transistor (IGBT), and/or a junction field effect transistor (JFET) may be used in place of or in conjunction with the devices described herein. The transistors may be depletion mode devices, drain-extended devices, enhancement mode devices, natural transistors, or other types of device structure transistors. Furthermore, the devices may be implemented in/over a silicon substrate (Si), a silicon carbide substrate (SiC), a gallium nitride substrate (GaN) or a gallium arsenide substrate (GaAs).

References may be made in the claims to a transistor's control input and its current terminals. In the context of a FET, the control input (or transistor control terminal) is the gate, and the current terminals are the drain and source. In the context of a BJT, the control input is the base, and the current terminals are the collector and emitter.

References herein to a FET being “ON” means that the conduction channel of the FET is present and drain current may flow through the FET. References herein to a FET being “OFF” means that the conduction channel is not present so drain current does not flow through the FET. An “OFF” FET, however, may have current flowing through the transistor's body-diode.

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/−10 percent of that parameter or, if the parameter is zero, a reasonable range of values around zero.

Modifications are possible in the described embodiments, and other embodiments are possible, within the scope of the claims.

What is claimed is:

1. An apparatus comprising:
a rectifier circuit having a first terminal, a second terminal, a third terminal, and a fourth terminal;
a first capacitor having a first terminal coupled to the first terminal of the rectifier circuit, and a second terminal;
a second capacitor having a first terminal coupled to the second terminal of the rectifier circuit, and a second terminal;
a driver circuit having a first output coupled to the first terminal of the first capacitor, and a second output coupled to the second terminal of the second capacitor;
a first receiver having a first input coupled to the first terminal of the rectifier circuit, a second input coupled to the second terminal of the rectifier circuit, and an output;
a second receiver having a first input coupled to the third terminal of the rectifier circuit, a second input coupled to the second terminal of the rectifier circuit, an enable input coupled to the output of the first receiver, and an output; and
a switch having a control input coupled to the output of the second receiver.

2. The apparatus of claim 1, further comprising a logic gate having a first input coupled to the output of the first receiver, a second input coupled to the output of the second receiver, and an output coupled to the control input of the switch.

3. The apparatus of claim 1, wherein the rectifier circuit includes:
a first diode having an anode coupled to the first input of the first receiver, and a cathode coupled to the first input of the second receiver; and
a second diode having an anode coupled to the second input of the first receiver, and a cathode coupled to the second input of the second receiver.

4. The apparatus of claim 3, further comprising:
a first resistor having a first terminal coupled to the cathode of the first diode, and a second terminal; and
a second resistor having a first terminal coupled to the cathode of the second diode, and a second terminal coupled to the second terminal of the first resistor.

5. The apparatus of claim 4, further comprising:
a third diode having an anode, and a cathode coupled to the anode of the first diode; and
a fourth diode having an anode coupled to the anode of the third diode, and a cathode coupled to the anode of the second diode.

6. The apparatus of claim 5, further comprising:
a third resistor having a first terminal coupled to the anode of the third diode, and a second terminal; and
a fourth resistor having a first terminal coupled to the anode of the fourth diode, and a second terminal coupled to the second terminal of the third resistor.

7. The apparatus of claim 6, wherein:
the first receiver has an input voltage terminal coupled to the second terminal of the first resistor, and a reference terminal coupled to the second terminal of the third resistor; and
the second receiver has an input voltage terminal coupled to the second terminal of the first resistor, and a reference terminal coupled to the second terminal of the third resistor.

8. A circuit, comprising:
a capacitive isolator having a first input, a second input, a first output, and a second output;
a rectifier circuit having a first terminal coupled to the first output of the capacitive isolator, and a second terminal coupled to the second output of the capacitive isolator, a third terminal, and a fourth terminal;
a first receiver having a first input coupled to the first output of the capacitive isolator, a second input coupled to second output of the capacitive isolator, and an output;
a second receiver having a first input coupled to the third terminal of the rectifier circuit, a second input coupled to the fourth terminal of the rectifier circuit, an enable input coupled to the output of the first receiver, and an output; and
a switch having a control input coupled to the output of the second receiver.

9. The circuit of claim 8, further comprising a logic gate having a first input coupled to the output of the first receiver, a second input coupled to the output of the second receiver, and an output coupled to the control input of the switch.

10. The circuit of claim 8, further comprising a driver circuit having a first output coupled to the first input of the capacitive isolator, and a second output coupled to the second input of the capacitive isolator.

11. The circuit of claim 10, wherein the capacitive isolator includes:
a first capacitor having a first terminal coupled to the first output of the driver circuit, and a second terminal coupled to the first terminal of the rectifier circuit; and
a second capacitor having a first terminal coupled to the second output of the driver circuit, and a second terminal coupled to the second terminal of the rectifier circuit.

12. The circuit of claim 8, wherein:
the first receiver is configurable to:
detect a differential voltage at the first and second outputs of the capacitive isolator; and
provide at the output of the first receiver, a signal indicating whether the differential voltage is detected;
the second receiver is configurable to:
detect a differential current at the third and fourth terminals of the rectifier circuit; and
provide at the output of the second receiver, a signal indicating whether the differential current is detected.

13. The circuit of claim 8, wherein:
the rectifier circuit includes:
a first diode having an anode coupled to the first input of the first receiver, and a cathode coupled to the first input of the second receiver;
a second diode having an anode coupled to the second input of the first receiver, and a cathode coupled to the second input of the second receiver;
a third diode having an anode, and a cathode coupled to the anode of the first diode; and
a fourth diode having an anode coupled to the anode of the third diode, and a cathode coupled to the anode of the second diode; and
the rectifier circuit is configurable to provide power harvested from a common mode noise signal to the second receiver.

14. The circuit of claim 13, wherein the rectifier circuit includes:
a first resistor having a first terminal coupled to the cathode of the first diode, and a second terminal;
a second resistor having a first terminal coupled to the cathode of the second diode, and a second terminal coupled to the second terminal of the first resistor;
a third resistor having a first terminal coupled to the anode of the third diode, and a second terminal; and
a fourth resistor having a first terminal coupled to the anode of the fourth diode, and a second terminal coupled to the second terminal of the third resistor.

15. The circuit of claim 14, wherein:
the first receiver has an input voltage terminal coupled to the second terminal of the first resistor, and a reference terminal coupled to the second terminal of the third resistor; and
the second receiver has an input voltage terminal coupled to the second terminal of the first resistor, and a reference terminal coupled to the second terminal of the third resistor.

16. A switch circuit, comprising:
a pass transistor having a first terminal coupled to an input terminal, a second terminal coupled to an output terminal, and a control terminal;
a transistor driver having an input, an output coupled to the control terminal of the pass transistor, and an input;
a rectifier circuit having a first terminal, a second terminal, a third terminal, and a fourth terminal;
a first receiver having a first terminal coupled to the first terminal of the rectifier circuit, a second terminal coupled to the second terminal of the rectifier circuit, and an output coupled to the input of the transistor driver;
a second receiver having a first terminal coupled to the third terminal of the rectifier circuit, a second terminal coupled to the fourth terminal of the rectifier circuit, and an output coupled to the input of the transistor driver;
a capacitive isolator having a first input, a second input, a first output coupled to the first terminal of the rectifier circuit, and a second output coupled to the second terminal of the rectifier circuit; and
a differential driver having a first output coupled to the first input of the capacitive isolator, and a second output coupled to the second input of the capacitive isolator.

17. The switch circuit of claim 16, further comprising a logic gate having a first input coupled to the output of the first receiver, a second input coupled to the output of the second receiver, and an output coupled to the input of the transistor driver.

18. The switch circuit of claim 16, wherein the capacitive isolator includes:
a first capacitor having a first terminal coupled to the first output of the differential driver, and a second terminal coupled to the first terminal of the rectifier circuit; and
a second capacitor having a first terminal coupled to the second output of the differential driver, and a second terminal coupled to the second terminal of the rectifier circuit.

19. The switch circuit of claim 16, wherein:
the first receiver is configurable to:
detect a differential voltage at the first and second outputs of the capacitive isolator; and
provide at the output of the first receiver, a signal indicating whether the differential voltage is detected;
the second receiver is configurable to:
detect a differential current at the third and fourth terminals of the rectifier circuit; and
provide at the output of the second receiver, a signal indicating whether the differential current is detected.

20. The switch circuit of claim 16, wherein the rectifier circuit includes:
a first diode having an anode coupled to the first input of the first receiver, and a cathode coupled to the first input of the second receiver;
a second diode having an anode coupled to the second input of the first receiver, and a cathode coupled to the second input of the second receiver;
a third diode having an anode, and a cathode coupled to the anode of the first diode;
a fourth diode having an anode coupled to the anode of the third diode, and a cathode coupled to the anode of the second diode;
a first resistor having a first terminal coupled to the cathode of the first diode, and a second terminal;
a second resistor having a first terminal coupled to the cathode of the second diode, and a second terminal coupled to the second terminal of the first resistor;
a third resistor having a first terminal coupled to the anode of the third diode, and a second terminal; and
a fourth resistor having a first terminal coupled to the anode of the fourth diode, and a second terminal coupled to the second terminal of the third resistor.
